(19) United States
(12) Patent Application Publication
(10) Pub. No.: US 2009/0322328 A1
(43) Pub. Date: Dec. 31, 2009

(54) E-field imaging and proximity detection using a spatially and temporally modulated source

(76) Inventor: Thomas G. Cehelnik, Tucson, AZ (US)

Correspondence Address: Thomas G. Cehelnik, 8300 E. Ocotillo Dr., Tucson, AZ, 85750, US

(21) Appl. No.: 12/383,254

(22) Filed: Mar. 20, 2009

Related U.S. Application Data
(60) Provisional application No. 61/070,099, filed on Mar. 20, 2008.

(51) Int. Cl. G01R 33/48

(52) U.S. Cl. 324/309

(57) ABSTRACT

A method and apparatus is described to image a body using electric fields. The electric field is apply to the body from a well controlled electron beam that deposits charge on a glass plate at a particular time and spatial location. This is demonstrated by using the ubiquitous CRT computer monitor. The method is useful in medical imaging and for nondestructive testing. An advantage of the electric field imaging is it requires no ionizing radiation. The use of the computer display allows for proximity detection of a body. A smart control is drawn on the video screen by a program. The control produces and E-field source that occurs at known time in the video refresh. A proximate E-field sensor is used to detect the changes in the signal produced by the button. Changes in the signal level are associated with a proximate body to the button. Detection logic is used to instigate the action of the control.

### CROSS REFERENCE TO RELATED APPLICATIONS

This application is related to provisional application 61070099.

This is a regular patent application and is to receive the benefit of the provisional application 61070099 with filing date of Mar. 20, 2008 having title “E-field Imaging and Proximity Detection Using a Spatially and Temporally Modulated Source”.

### STATEMENT OF FEDERALLY SPONSORED RESEARCH OR DEVELOPMENT

Not applicable

### REFERENCE SEQUENCE LISTING OR COMPUTER PROGRAM

Not applicable

### FIELD OF INVENTION

Field of this invention is the art of noninvasive medical imaging, nondestructive testing, and the imaging of objects for security screening. It also includes the field of proximity sensing. One expanding market for proximity detection its application to the control of computers. The disclosed technology makes possible new touch screen, proximity detection, and identification sensing through the use of an E-field camera built into the video screens of computer and TV displays.

### SUMMARY OF THE INVENTION

### E-field Imaging:

A new E-field imaging method is revealed that is useful for medical imaging, nondestructive testing, and security screening. E-field imaging yields pictures of a body in a way similar to X-rays without the safety concerns of using ionizing radiation. A novel but nontrivial method was used to demonstrate the concept of the invention. We have showed herein that it is possible to use E-field sensors to capture signals from an array of charges. A method is described as to how to detect an process the signals, as indicated by using a Cathode Ray Tube or CRT or LCD display monitor.

The computer display monitor has the concept of being able to turn on pixels in time as some particular spatial location in the display plane. This is ideally what is wanted for imaging. Also what is wanted is the charge of voltage is to be places at the pixel. Practically though, the front of the display conducts the potential across the screen and localization is far from ideal. Nevertheless, we demonstrate the concept of imaging with the hypothetical spatial and temporal array. A real array can conceivably be produced by removing the display diodes in an LCD display, and only have a matrix of electrodes pixels. The image is obtained by placing an object between the location of the source and an E-field sensor measurement to create an image formed from signal power transmitted or conducted through the body. The image shows areas of attenuation with respect to position much like an X-ray image. More specialized equipment can be designed using the invented technology that could potentially offer spatial resolution similar to or possibly even better than an X-ray image.

Others researchers have discussed using E-field imaging that places a pattern of electrodes on the body, transmit a voltage on one and receive voltage level on others. This method is an inverse method to get the image. It is limited by unknown current that flow through the body to the electrodes.

In this invention, we offer two approaches, one, a non-contact E-field attenuation method with a receiver that is electrically isolated or in contact with the body; and another a contact applied E-field but isolated receiver. These methods minimize substantially conduction currents. Plus we can use DC applied fields that do not generate the AC currents associate with Faraday's law, displacement currents.

Note by spatially placing the source, or modulating and repeating its application in time at the specified location, signal can be captured and processed. Next, the spatial location is moved and the signal is repeated. We could also spatially apply an AC signals of different frequency at each spatial location in a source field array. Such an array can be a planar 2-D array, or a curved array. The E-field receiver is on the other side of the body.

Tomography processing is also claimed where the source and receiver form a line through the body, and this line is rotated about the body. From this approach, we can get an image of the attenuation in 3D space within the body. The attenuation along the line-of-sight is used.

### Smart Control Summary

The new E-field imaging technology also offers computer users and program developers the ability to make and use smart controls. The E-field array has the ability to transmit or receive signals from or at an area located on the video screen, called the control area. The body moves proximate the control location and an E-field receiver either in the screen or coupled to the persons body picks up the signal. Conversely, the body has a transmitter that senses a signal that is receive at the control location. The disclosed technology using E-field sensors functions as touch-screen and motional command screens, too.

Smart controls are buttons on a video screen that conventionally respond to mouse clicks, but now are made to respond to proximity, gestures, touch, and even recognize ID signatures. The ID recognition might be to recognize a unique set of pores within a persons hand when it is placed on the screen or a key reading, or a tag in a keycard or money, or RF ID signal that is read by an E-field sensor. These smart controls are all referred herein as controls.

The smart controls are created either in transmit TX or receive RX or transceiver XCVR mode. In TX mode, we use an E-field source connected to the screen having a temporal or spatial variation on the video display or smart pad. The display signal can be created by generating an E-field originating from the video signal applied to the display pixels within the control. In RX mode, the display has embedded E-field receivers that persons body or a wand conducts a safe level E-field signal. The TX signal is time synchronized with the receiver located a specified spatial location in the screen. Hence the receiver at an (x,y) will turn on at the same time the TX signal is sent to the body. When the persons finger approaches the proximity (x,y), the receiver recognizes the presence of the signal, and the software fires a control signal.

In XCVR mode both transmitters and receivers are embedded. The signal is electrically coupled with the persons body or finger between the TX and RX antennas. When the RX signal for a receiver located at (x,y) exceeds a threshold, an event has occurred, and a programmed control signal is fired. The transmitter can be b on a transparent electrode configuration on the display material such as glass or plastic, or can be hidden behind the display electronics.

In this patent application, we shown here that video signal from an analog VGA adaptor are sufficient to allow for detection and recognition of E-field signals without physical contact to the source. This was done by looking at video displays, both CRT and LCD video displays. What is needed is a needed are E-field sensor technologies and system to generate a localized signal. Source multiplexing and microelectronic fabrication is required. This technology is available.

Spatial location of a turned on Pixel was the intent. To see this with the CRT and LCD a difference amplifier is needed to process the signals between two E-field sensors. Signals from different location s of lines and pixels were likely observe as different amplitudes were seen. Our invention is to have the ability to use a standard CRT or LCD to turn on a pixel region and have an E-field come directly from it. Our data in this disclosure shows we can see video signal from a stand off, and see the attenuation of the body.

It will take further work to use a standard video display because the conduction of the conductive glass in a CRT sends the pixel signal at the speed of light to the whole face of the glass display. Thus spatial localization is more difficult; but the temporal signal is seen. Thus what is really needed is an apparatus that provides a voltage with enough charge to electrify an spatially positioned element. Then the signal is detected from that element using the E-field system. Thus it is proposed a switched array of source elements. Light can perhaps be used to generate photoelectric effect that electrifies a pixelized element. Anyway, either a video screen or panel is claimed that has the ability to program and control the spatial and temporal location of an element.

Smart tablets like the Tablet PC computer by Microsoft and others have display designs uses transmitters and receivers to detect a resonance frequency in a wand. Then a receiver in the screen picks up the resonance energy. The invention herein gives more range and is an extension of the table pen technology.

Perhaps a table PC hover mode is possible where the wand is detected above the screen. If this is so the range is limited. This has not been observed on the SmartBoard® by SmartBoard corporation that uses a touch screen technology of resistive wires.

Any of these technologies do not show how to detect a persons control surface such as a hand or finger more than a few millimeters from the screen. What is needed is a way to detect the conduction changes in an E-fields due to the presence of a body away form the screen. What is needed to do this is to have a system that can detect localized changes in E-fields due to conduction or attenuating the E-field signals. Plus, what is needed is the ability to embedded E-field sensors that give high impedance and high sensitivity to small electrical signals into display screen devices, or give the screen the ability to transmit signal at a control display location that can be discerned by an E-field sensor system.

### Description of Smart Controls Detailed Summary

The concept of smart controls has not been described or claimed elsewhere. Smart controls are displayed as buttons on video screens or embedded in the screen background like in a window, window bar, or menu where they may or may not be seen. They activate computer operations or commands upon recognition of signals from an E-field sensors signal embedded within or proximate the display. For example, they may be at the either at the edges, or in the base, or can off board in remote equipment such as headphones, or loudspeaker, or within a workstation. Once the controls are defined in shape and location, the E-field sensor and processor listens for the energy produced from the control. A modification to the signal level is indicative of a body being proximity to control button. Such modifications are discussed previously by Cehelnik, and they also depend upon the E-field sensor type being used. All that is really necessary is the E-field from the know location of the buttons that is used to produce a background signal. Then the E-field sensor is used to measure changes from the background level.

The signal processing first involves time gating the signal coming from the pulse produced by the pixels in the control region. Time gating of the E-field sensed signal is done with the location information of the button, and the video control signals. The signal burst is collected for each video frame. A measure of the burst energy in each frame is performed by A bandpass filter the burst to capture a frequency tone, and then rectifying the burst followed by a sample and hold circuit. The voltage on the sample and hold is then sampled by and ADC or switched from frame to frame to create a button background signal that is sampled at the frame rate. Change in this signal level are is used to indicate power changes relative to the background when no body is proximate the sensor. Other direct sampling methods exist, but the idea is a measure of the energy coming from the button is monitored. For example, a FFT of the button burst may be performed. The amplitude of the peak gives such a measure. By bandpass filtering or bandlimiting a tone level is extractable. The level of this signal measurement is a measure of the background signal.

When the body is placed in between the source field and the E-field sensor a decrease in level is indicated. This was observed using the MCS2 sensor, and generating a current limiting voltage from a clock generator that had a frequency of 11 kHz. If the body touches the antenna then the E-field sensor signal can go higher. If the body is grounded the signal still decreases between the source and the sensor. On the other hand if the body is grounded and touches the E-field source button, then signal in the detector will decrease the most, relative to the average background signal. The background signal changes from about 0.2 set to 5 seconds for a gesture, so higher frequency variation due to a body need not be detected.

Standard PC tools like Microsoft's Visual Basic, and Microsoft's Office Products can offer programs and Web pages controls. These products as well as other programming languages will be able to create control buttons that can be made to link electronic actions like mouse clicks, keystrokes, or macro commands with proximity detection, motional commands, and bioidentification. Other peripheral devices such as light pens, game accessory like swords, wands, can also be sensed by the control buttons and linked to a computer program input to perform some electronic operations.

Control buttons appearing on a computer or TV display, or equipment can be activated with E-field proximity detection. Sensing buttons on a display screen are programmed to appear at a location with specific call back actions. Then changes in the E-field signals associated with those controls are sensed. Signal detection logic is then used on the sensed signals to make possible the activation of programs and other computer operations.

A new and novel method is disclosed that uses a video display to generate a spatially and temporally modulated E-field source. The video displays, like CRT, LCD, plasma produce an E-field signature. When display pixels are energies with a voltage or charge, they act as an E-field source. A novelty is a pixel source is small, precisely located, closely spaced, and is turned on at a known time relative to a display clock, and it has an amplitude related to the illumination or color.

The E-field imaging system is made from the arrangement of components in the system. It is comprised of an E-field source so as described. It also is comprised of an E-field sensor, E-field signature detection, and processing. A system is disclosed herein made with the technology currently available. Those skilled in the art will also be able to construct specific systems tailored to their sources, displays, or sensors, but the idea is the same as disclosed and covered the claims.

### ASPECTS OF THE INVENTION

Aspects of this invention are to place a E-field source at a precise location and time and with known duration, by using a means of placing or switching to a spatial location with a temporal period an electric potential from a charge source. Such a means may be achieved with an electrode beam along with a means of holding the charge at a, both of these are found within a CRT display. A CRT holds electrons or charge from the electron gun onto the screen via the phosphorus coating material. Another mean is to use a multiplexed or matrix switched voltage source such as a battery, or power supply; or a switched charge source like a capacitor. Such a systems is found within a matrix computer display device such as an LCDs or plasma video display device, or it can be constructed with a array of electrodes with a means of connecting them to an electrical source of charge or voltage.

It will take further work to use a standard video display because the conduction of the conductive glass in a CRT sends the pixel signal at the speed of light to the whole face of the glass display. Thus spatial localization is more difficult; but the temporal signal is seen. Thus what is really needed is an apparatus that provides a voltage with enough charge to electrify an spatially positioned element. Then the signal is detected from that element using the E-field system. Thus it is proposed a switched array of source elements. Light can perhaps be used to generate photoelectric effect that electrifies a pixelized element. Anyway, either a video screen or panel is claimed that has the ability to program and control the spatial and temporal location of an element.

The method of E-field imaging is to us a means of precisely placing an E-field source within space and time along with an E-field sensor or plurality thereof to:

A: Sense variations or the contrast in the electrical properties of the body or material being scanned, by providing a measure or indicator of:
1. The E-field signal occurring when the E-field travels from the source to the detector;
2. Changes of the signals in A.1, as the relative source vector connecting the source and the detector changes in the scan;
3. Process and displaying the Signals in A.2 in an image or movie or output a signal representative a view through the body;
   B: Sense the proximity of the body to the source defined as a pixel region of the video display and by providing a measure or indicator of:
1. The E-field signal occurring when the E-field travels from the source to the detector when the source is an object drawn on a video display screen or region or smart button on a video display used to produce an E-field source;
2. Sense changes of the signals in B.1 with an E-field sensor proximate the source and a body and compare signal level received with and without the body proximate the source;
3. Make a decisions and instigate a computer or electronic response based on the signal comparison of B.2.
   C. Focus the E-field by creating a highly digitized time series of sampled E-field sensor data set from a small pixelized region of the source and raster that source across all source locations with the sensor electrode located behind the body at the point where the collected data will be focused by
1. Time shift the received data from each source to allow for phase adjustment or time differences due to propagate path difference to the sensor or detector;
2. Modulate the amplitude data in C.1 with a high frequency carrier within the bandwidth of the digitized data;
3. Apply digital phase shifting, apply an exponential phase factor to each data set in C.2 to focus or beamform the signals from the source pixels as if they were a from an array of sources, and focus the result at a point or along a vector from the source array center through the body to the sensor location;
4. Process the data in 3 as the superposition of the pixel data sets each weighed by the focus weights or phase to construct the focused signal amplitude;
5. Move the sensor location and perform steps 1 through 5, and then display the contrast in the focused amplitude with position of focus to make an image or sliced image of the body;
   D. Detect the sensor signal through the body by cross correlation, whereby a pattern of pixel is applied a sequence of pixels in time to each scanned line, and use a sensor located on the source screen to capture the signal and;
1. Capture a line scan of the signal at the sensor;
2. Cross correlate the signal captured in D.1 with the screen signal of the sent pattern;
3. Use the peak of the result in D.2 to find the signal amplitude for of the sensed E-field that propagated through the body.
4. Plot as an image the results in 3;

### BRIEF DESCRIPTION OF DRAWINGS

The following drawing will assist in understanding the invention.

FIG. 1 shows a photo of DC source 0.1 inch spaced electrodes placed on top of finger running along the finger for scanning to identify possible swollen middle finger knuckle.

FIG. 2 shows a diagram of DC source Electrodes using MCS2 sensor with DC reference electrode to balance DC offset to allow for AC amplitude decrease with DC field input to sense electrode. Figure is placed upon a notebook with electrodes below a glass plate. Electrodes are ½ inch wide by about 10 inches long, and about 0.010 inch thick. The finger is placed on a glass insulator. The sensor can have a common ground with the DC applied source, or a differential measurement on the sensors can be made relative to another reference potential. The DC field produced by voltage source V can also have an AC component to aid in processing. In this case, electrode AC signal would be lower frequency that the applied filed so, we can sense a decrease in this AC field. The AC applied field is uniform through the body, so spatial localization of the return signal is associated with the electrode signal applied.

FIG. 3 shows Positive Feedback to a reference electrode from the output of the first amplifier. The amplifiers are TL082 JFET types, supply voltages not shown, but running on +/−9 Volts split battery supply. The E-field sensor amplifiers are TL-082 or equivalent JFET input types. Voltage on the DC bias is adjustable from +/−9V, or could also be an antiphase AC signal to reduce background levels if needed to avoid saturation.

FIG. 4 shows the oscilloscope captured scans of my finger for each frame of the scan, where a frame is for combing the electrodes with a negative 9 Volt source. The signal is a 60 Hz background AC that has amplitude modulated by DC field that passes through the finger. The frames are identified as the data between the deep drop in AC signal. The second full frame and fourth full frame in the screen capture show a common appearing signature that has a dip in the AC signal level. The signature indicates a changing AC level or corresponding DC level due to possible swollen or broken knuckle.

FIG. 5 Shows the effect of directly driving sensor electrode with DC voltage. It causes the AC amplitude to decrease. Shows the sensor AC signal output signal is modulated by the direct contact with probing DC potential.

FIG. 6 shows the E-field Image Scanner as a block diagram the CRT scan system. 1 is CRT, 22 is an E-field sensor on the glass of 1, 16 is a computer with 20 the Video card, and 14 a VGA signal splitter, 18 is a data hard drive, 10 it's the line trigger circuit programmable to trigger on a line using the microcontroller, 12 is the digital oscilloscope, 2 is another E-field sensor and 6 is a glass plate, where a 10 inch vertical antenna is glued on acetate, and taped to the glass, smaller antennas do work at sacrifice of signal level, but offer more spatial resolution, 8 is a ground plane aluminum cookie sheet that is grounded and placed about 2 inch from the glass, so the DC bias on the opamp is controlled. The E-field sensor is LT1169 without bias resistor and then a high pass signal single pole filter capacitor of 470 pF, and a resistor 22 kOhm, to give a corner frequency of about 15 kHz. Other E-fields sensors work too, but to get high resolution we want to use a broadband E-field sensor like that in FIG. 10. The input impedance is about 2.5 Mhos, for the values of R1 and R2 each equal 5 MOhm. Larger values are possible to give mores sensitivity. If the bias resistors are eliminated the device is real sensitive to DC fields. A Reference electrode can be used in this case just like for the opamp case. The discrete FET amplifier of FIG. 10 has a high pass filter at about 160 Hz. This filter can be increase to reduce sensitivity to DC fluctuation that are out of the band of the video signal. It could be made to have the same 15 kHz value as before in the chip amplifier. The key point is the amplifier allows for the detection of static placed charge, and that can be in the form of a capacitor plate formed on a display screen. Those skilled in the art can change the filtering and the background noise, but component selection and electromagnetic shielding of the apparatus. It is understood that these deviations for what is explained herein are part of the this invention.

FIG. 7—Shows the timing architecture of a coherent scanned E-field imaging system.

FIG. 8—shows a trigger circuit used to trigger the oscilloscope on the frame and line synchronization signals going to the video monitor that acts as a E-field source.

FIG. 9—shows a line counter using the trigger signals shown in FIG. 8

FIG. 10—a) Shows the CRT screen display at resolution is 800×600 at 60 Hz frame rate of a black screen with a white Vertical strip used to generate signal captured in b). b) shows the detected E-field signal using the Opamp Imaging E-field sensor of FIG. 12. The drop E-field signal corresponds to when the electron beam is generating the white portion of the CRT screen display with antenna glued to an acetate sheet and taped to the glass. The signal was from a vertical white line on the CRT.

FIG. 11 a) shows a screen shot of the CRT. Resolution is 800×600 at 60 Hz frame rate. FIG. 11 b) shows the detected E-field signature using setup in FIG. 6. The signal is detected at a distance of 8 inches away from CRT using the Opamp Imagine E-field sensor of FIG. 12. The sensing and reference antenna electrodes are on glass sheet [6] of FIG. 6 and is glued to an acetate sheet and taped to the inner side of the glass. The signal was from a vertical white line on the CRT. The signal is reduced in amplitude compared to FIG. 10 b) because it is located at further distance away.

FIG. 12—shows the opamp amplifier using the reference electrode 8 to push the DC bias toward 0, so the AC sensitivity is maximum.

FIG. 13—show a broadband version of an E-field sensor. This sensor is going to be able to construct the image from the screen that was sent to the sensor by conditioning its output and sending to another monitor color signal, along with the frame and line synchronization signals. Also this sensor allows for digital data transmission from a E-fields source, such as a wire modulated with an audio signal or digital data, to the E-field sensor in a headphone set, or other receiver. This sensor was able to see the signal from the CRT at stand off distance of 10″ or more. It did not require the reference electrode, since is has a high pass filter. The sensitivity at high frequency was not affected by the DC bias, since the amplifier has a DC bias voltage divider network fixing the input DC voltage. One can eliminate R1 and R2 for higher sensitivity, but then a reference electrode is needed to control and stabilize the bias input of the FET.

FIG. 14—parts a), b), and c) together shows a circuit demonstrating the use of negative feedback, when operating a Motional Command Sensor on an LCD monitor. There is a distinct DC field from LCD displays, and it takes a reference electrode of signal opposite to the output bias of the opamp to compensate. The reference electrode is running in the wiring to the antenna and with some part exposed near the sense antenna. This is called negative feedback mode, or opposite DC bias, and also is useful with antiphase signal to the 60 Hz background. The sensor can be turned to the background of the AC line frequency, frame refresh rate, or the line frequency of the LCD display. This is why the filtering is a in a block diagram. Also, by doing this approach, the bias coming from the first stage of the amplifier is kept near zero volts. To get a AC modulation a DC signal needs to pass as shown. The bias to the opamp U3A is adjusted with a potentiometer to give the −6.6 Volts operating bias. This is adjustable for different JFET chips and operating voltages, but the effect and application has been explained and is claimed. The MUX is shown as a physical switch thus presenting the high input impedance to the opamp sensor. If this impedance is compromised by the part then the MUX shown, should be moved after the first opamp.

### BACKGROUND OF THE TECHNOLOGY

The technology uses safe electrostatic or quasistatic electric fields called E-fields. Cehelnik previous patent applications have taught various means to make sensors that detect E-fields, both DC and AC signals, active and passive detection, with the body at a floating or fixed potential, a voltage relative to ground, and augment with modulation. The Motional Command System(MCS), proximity sensing, and E-field Imaging were introduced in Cehelnik's previous patent applications.

Now in this application Cehelnik teaches how to usefully use E-field signals detected when precisely controlling the time and location of an electrostatic or quasistatic source of E-fields. Cehelnik shows herein that having a priori knowledge of the E-field source location with time, that this information makes possible the precise association of a E-field signal with the physical properties of the body that include its spatial location at some time, and the electrical properties of the body.

A point of operation to note is when no source currents flow into the body, the potential measurements made with the E-field sensor are decoupled from magnetic equation and the becomes need to measure currents flowing though the body. This is our case, because the method of application only applies an electric field, and current are limited by high impedance paths between the body and the E-field generator's charge source. Interesting effects of applying magnetic fields to the body and then performing E-fields measurements are also of potential interest, and high sensitivity of the E-field measurements shown here can also detect potential changes due to charge E-fields, or internal electromotive forces and current interactions due to Faraday's law, and other coupling of Maxwell's equations.

Proximity detection and imaging are both made possible with the E-field technology disclosed here. When the location of the body and the source E-field source location are known a priori, then electrical property variations in the body are indicated by observed variations in the E-field signals. If the electrical properties, or the affect of the body on the electric field is known, for example the AC or DC signals increase or decrease for the sensor type and body properties, then the proximity of the body to the E-field source is indicated by the variation in the E-field signal.

### History:

In a prior patent application A Method of Detecting Charge and Proximity, Cehelnik discloses an apparatus and method for electrically scanning an object by moving the body past a sensor with a modulated source. The modulated source helped to identifying the signal through time stamping and signal coding that could also act as a background signal. In this application, we wish to make an image without necessarily moving the body through a novel implementation of applying a background source.

An E-field image displays the contrast in the electric potential measurement about a body. This contrast is usually shown spatially in pixilated color map so it is possible to identify inhomogenities, but movies are also used to show the temporal behavior of the spatial contrast as well. To capture this image, measurements are made of the signal detected after passing through the body. The level of attenuation of the signal due to the body are plotted. In X-rays imaging, the more dense material attenuates the X-ray. In E-field imaging, the observed electric potential is attenuated by the material having larger dielectric constant.

We see that to measure the attenuation, we must associate the attenuation as occurring over a defined path where the energy flows. This is taken as along the line between the source of the signal, and the location of the detector or sensor. Thus it is seen that there are combinations of possible position movements of the sensor and detector that are useful to allow for association with a line-of-flight. Using a machine is possible to move the source and the detector together while maintaining a fixed relative position, and rotating around the body. Without maintaining relative position between the source and detector, either the source or the detector can move.

Arrays are useful and convenient to provide some movement of source or detector positions without having to translate the machine. The vast application of E-field imaging may benefit from one configuration over another. What is disclose herein can be modified to a different arrangement, but never-the-less the invention still applies to these configurations.

E-fields detectors require a receive antenna or equivalently called an electrode. The sensor amplifier need to be kept closely to the antenna for high sensitivity, thus makes it difficult to have a switched antenna to a common amplifier. In other words, each detector should have its own amplifier to buffer the signal. In an array each detector element should also be similar in sensitivity, and should be closely spaced to get a high spatial sampling of the field. Mechanical and size constraints along with electrical complexity of having switching and amplifiers for each sensor channel increase cost and complexity of this having detector arrays. This is may not be a problem for advanced systems, but for a inventor this is not a natural path.

### E-Field DC Imaging:

Next it was realized that an array of sources is more tractable and than moving the receivers, so this is the first approach. Latter the E-field antenna of there receiver can be moved to aid in further processing. A single receiver is simpler at first because there is no need for different amplifiers but just a way to switch a matrix of small source E-field elements. As a preface to a source field array design on a circuit board, electrode pins spaced 0.1 inches apart were used to apply a potential of 9 Volts to my finger. The scan was made by mechanically by moving the battery wire across the teeth of the electrode pin array. A fixture was used to hold the electrode array.

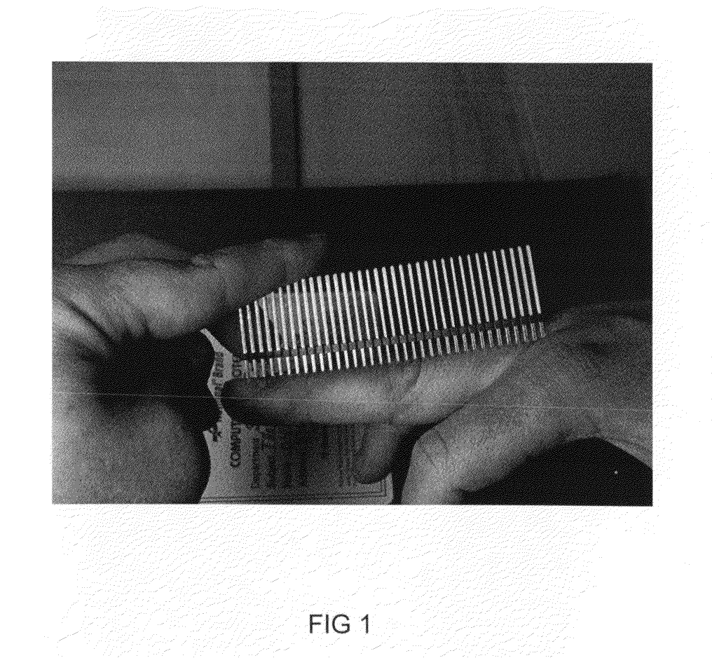

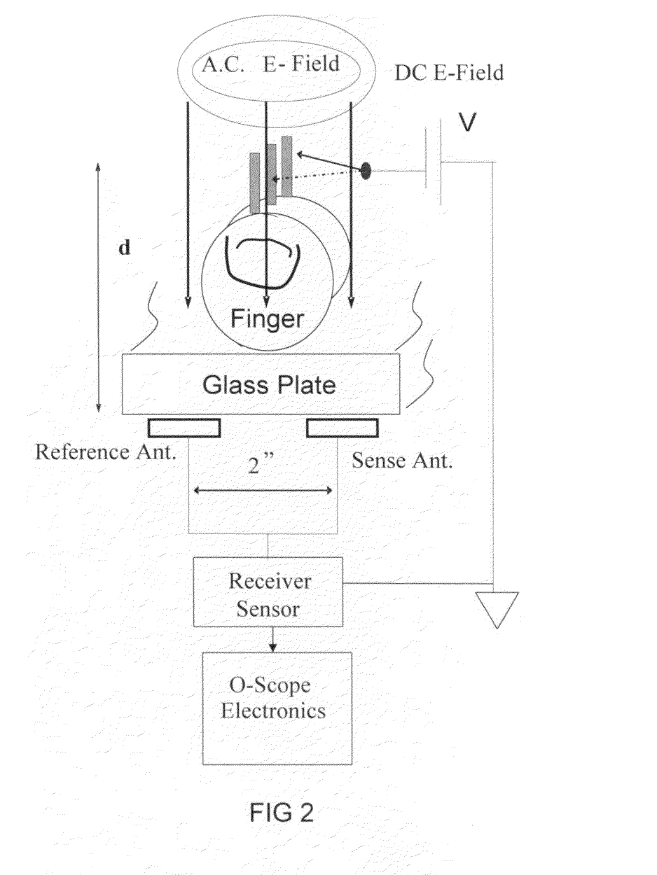

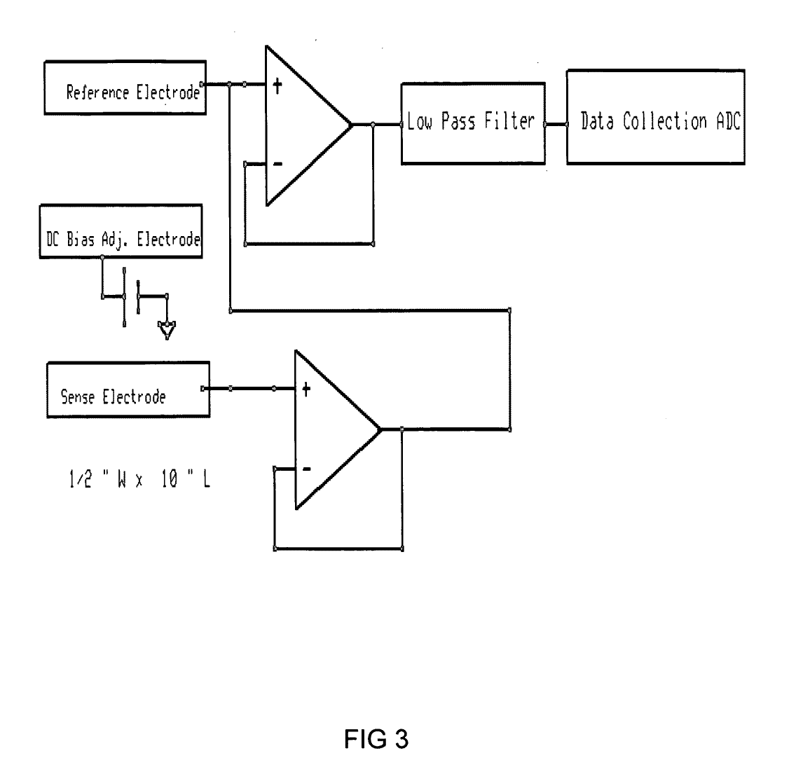

The MCS2Sensor was used to capture the E-field after passing through a 150 page notebook, and a ⅜ inch laminated plate glass. The DC field from the teeth was believed to decrease the background signal. With the background assumed level, then any changes in the DC field as it travels through my finger would show up as changes in AC amplitude of the background. FIG. 1 shows a photo of the electrode on the finger. FIG. 2 shows a diagram of the setup using MCS2 sensor. FIG. 3 shows the oscilloscope captured scans. There appears some common structure between the scans, particularly when the electrode was applied over the middle finger knuckle. Repeated scans are needed to average results and remove noise. Also, an non-mechanical method of switching the applied voltage was needed. The results needed further captured.

This is possible with a printed circuit board and an analog multiplexer. The need for this approach has led to the use of a multiple layered circuit board to facilitate switching of a voltage source to the elements. The multiple layer then allows for potential shaping of the source field. Adjacent elements can be of opposite polarity or somewhere in between. This is still complex to build though, even thought good spatial resolution is possible by using small 0.006 in. wide wire trace on a circuit board with 0.006 in. spacing.

Both of the above approaches are possible, but still complex to be able to quickly get an image using E-field imaging. Now the need to have good control and apply a potential brought out the idea of a computer monitor. A cathode ray tube, CRT VGA computer monitor produces a well controlled raster of the electron beam. Also a digital monitor has very well positioned pixels. The effort began with an MCS, and then moved into a White Shark™ imaging system.

### MCS Using the Video Monitor as Background Signal:

First an MCS was made for a flat panel LCD display. The MCS system was made by placing electrodes on display protector glass cover. These electrodes were longer ½ inch wide copper strips, that had a RG-174 coax connected to the middle. Each strip was around the perimeter of the display cover. The vertical electrodes were 12 inches long and the horizontal ones were 13 inches long. The display protector also had a ground connection electrode that could be useful. If it is grounded the signal is lower. The coax is not quite needed when a buffer amplifier is include in the sensor antenna. In fact it adds shunt capacitance, and the preferred method is to have the amplifiers in an antenna circuit on thee edges. A reference electrode can be placed on the back of the antenna as well that has the shield attached. An electrically conducting paint on the inside of a edge trim is also possible to add more shielding, and give a neat appearance. The electrodes are connected together on the bottom of the glass in a circuit connection. In this connection the control, and USB communications is performed by a microcontroller, the CY8C24894 of Cypress.l

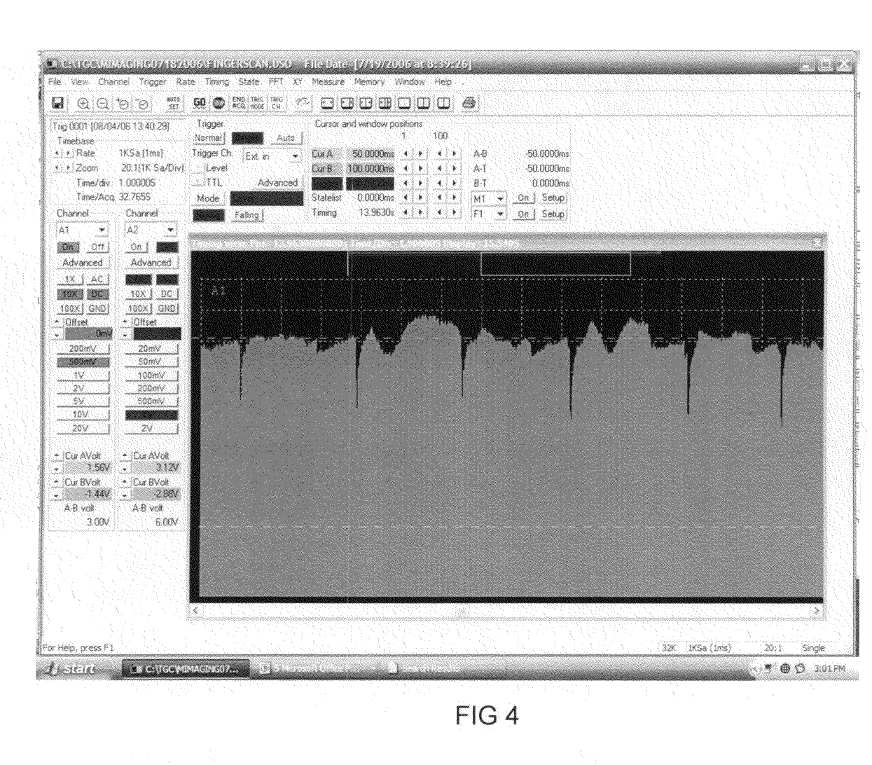

However, a problem was there is DC bias coming from the LCD monitor, that prevents the signal from having good control and reduces sensitivity. Also using the long coax with the shield not connected made it like useful as a reference electrode. What was done, is the output of the MCS2 sensor had a DC bias was small enough up to 4 volts. We now teach that is possible to drive this reference electrode with opposite polarity of the DC bias. In this application, neutralized the sensitivity of the cables to the proximity, and removed the bias. Hence, a circuit modification to the MCS2 is implement where the output of the MCS2 is low pass filtered and then inverted and sent out the reference electrode. To achieve the modulation due to the DC bias of a the control body, a bias was applied to the AC signal prior to going in the opamp buffer. In fact, a reference bias is set, and then a DC adjustments made to achieve the desired bias of about −6.6 V. The output of the circuit gives an amplitude of 1 volt peak. This circuit is shown in FIG. 4 and was made to run from a +/− split power supply using the TL082 but other circuits using the topology and methodology can also be made by those skilled in the art, but they are non-the-less covered in this invention.

The bias compensation circuit allows for a functional MCS operating with a series of sensor antennas that respond both to a grounded and ungrounded body. It is also found that other JFET opamps like the AD820, or part number AD820ANZ-ND from Digikey operate with a low voltage signal sided or dual supply and low voltage drive work well too, in the similar way. The feedback compensation of the reference electrode works well too, and allow for an automatic adjust.

Since the reference feedback preserves the AC sensitivity because there is minimum DC bias, a programmable gain control after the first amplifier is useful, to control the amplitude of the AC, and add the DC offset to be needed for a one sided ADC. A PSOC of Cypress CY8C24894 microcontroller is also used to provide USB connectivity, and programmable amplification and ADC data capture. An analog multiplexer MUX is also implemental that can switches the antennas. If the antenna is buffered like from the JFET, the CY824894 can multiplex the input, otherwise a MUX like the MAX308, MAX308CPE-ND from Digikey will work, but a clock, and switching logic needs provided. Cehelnik has shown this implementation in prior patent applications.

To further look at reducing supply voltage and wiring and hardware complexity for portable system, and a MPF102 amplifier is out to work well too as a front end to a lower input impedance and less costly op amp. FIG. 4 shows a FET circuit using a single sided supply, thus it reduces supply voltage line counts making it easy to mount near the screen.

The output of the N-channel FET amplifier can directly drive another opamp located further from the screen sensors. A N-channel FET driver was made with the MP102. The output of the MP102 driver is AC coupled to detect AC background. It is DC coupled if DC response is desired. If the output is DC coupled, then the next stage of amplification, needs the DC level to be shifted to remove the output bias from the FET. One option is to use an intermediate buffer amplifier of unity gain that can pass through the DC bias to a voltage divider or level shifter prior to driving a subsequent amplifier. Other DC compensation circuits are also possible.

The FET driver can also be used to drive wires coming from the sensor electrode, and even a MUX. The FET amp offers great bandwidth, and is what can be used to pick high speed signals. It can be followed by filters, a high pass, low pass or bandpass filter. The output of the filter is then driven into a broadband opamp amplifier that can offer voltage gain. After the FET stage other amplifiers JFET junction type or transistor input type can be used. It is not critical of the impedance once the FET driver was used. However, A JFET type is useful if it is desired to modulate the AC signal with DC signal.

The ability to capture high speed static induced signals, is facilitated by a broad band amplifier. Using a discrete FET is good if we want to have high bandwidth, like that of video frequencies. The spatial resolution of the scan is dependent upon the spacing between E-field sources, or pixels.

The spatial resolution requires an amplifier with a temporal bandwidth that is approximately 1 divided by the time the pixel is scanned. The bandwidth can be reduced if the E-field source stays on for more time due to response time of the pixel. Also a pointing system that holds the E-field source a spatial location for longer times will require less bandwidth. However, the duration of the scan will take longer. Also, the more duty factor is applied and thus there are signal power level considerations.

However for a scanning system, like a computer display monitor, this is equal to 1/(line scan frequency) further divided by the number of horizontal pixels in the scan. A line scan period may be for example about 25 microseconds. Then the time for a pixel is 25 nanoseconds. This corresponds to a needed bandwidth of about 50 MHz. The FET can have high bandwidth, when the junction capacitance is keep low, stray capacitance. Next the subsequent amplification must have the bandwidth for the gain desired.

A good 300 MHz bandwidth part at unity gain is the MAX4777EPA+, available as MAX4777EPA+-ND from Digikey. It is also a +/−5 Volt part. This part is used in and can have a gain of 6 and still have the 50 MHz bandwidth. When less image resolution, or spatial resolution of the CRT imager, smaller bandwidth is useful. At high frequencies, it is common to match impedance between input and output stages of the amplifier stages.

When E-field imaging can be done at lower resolutions, it is not necessary to have so much bandwidth. We have shown that using the LT1169 is a 5 MHz Bandwidth part that also runs on +/−5V, that we can capture a response from a 5 pixel wide screen running at 800×600 resolution. This is done on a CRT with glass of 13 inch wide by 10 inch high. This means there are 800 pixels per 13 inch, or approximately 0.01625 pixels/inch.

The FET amplifier can be mounted near to the electrode and operate with low supply voltages, like 3.3 V or 5 V. Power on a desktop MCS can then be drawn from the 5 Volts of the USB connection or low voltage 3.3 battery power. Another feature of having a buffer amplifier at the location of the electrodes is that a multiplexer or MUX can be used. The point of this investigation is indicated good options exist to facilitate the low cost manufacturing of a MCS system using E-field sensors.

It is in some instances useful to use the background signal from the monitor, either the line refresh signal 40-60 kHz, or the frame signal of about 60 Hz to 85 Hz. There are typical of monitor, CRT and LCD or plasma displays can have correspondingly higher rates. A MCS can be made from these background signals, where the body modulates the signal as detected by an E-fields sensor. Various modulations schemes are possible, on can be like those disclosed herein, or like that disclosed in the AC & DC coupled E-field sensor, or A Method of Detecting Charge and Proximity. The key is to select the signal by filtering. A discrete frequency can be bandpass filtered after the first stage of the amplifier. If sufficient signal level exists, a high pass filter in the front stage of the sensor first stage can also be used. It was not obvious that these signals from the computer monitors or video displays existed with E-field sensors that don't filter out unwanted background signals.

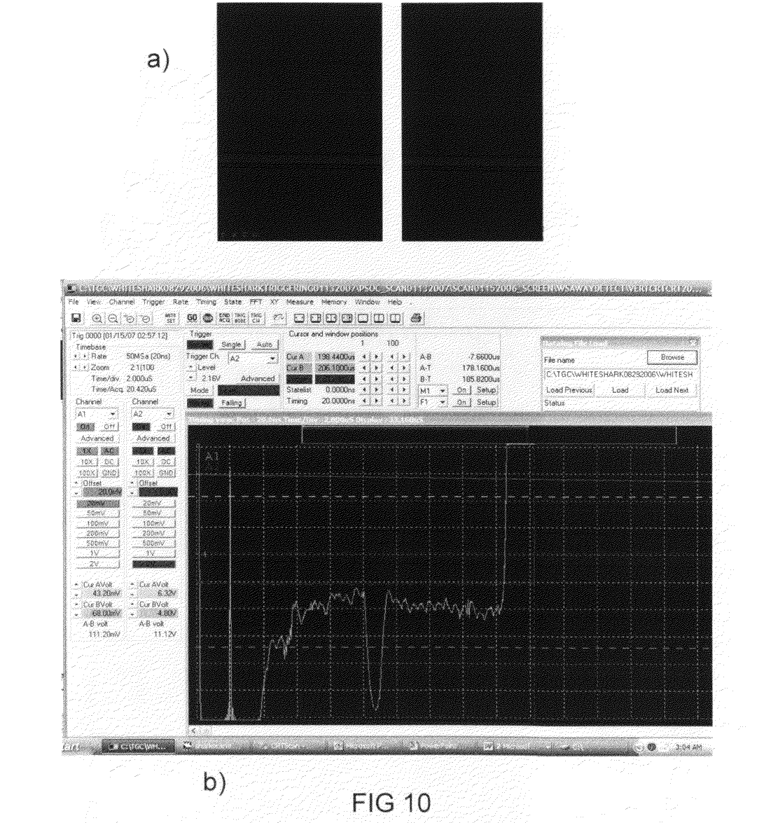

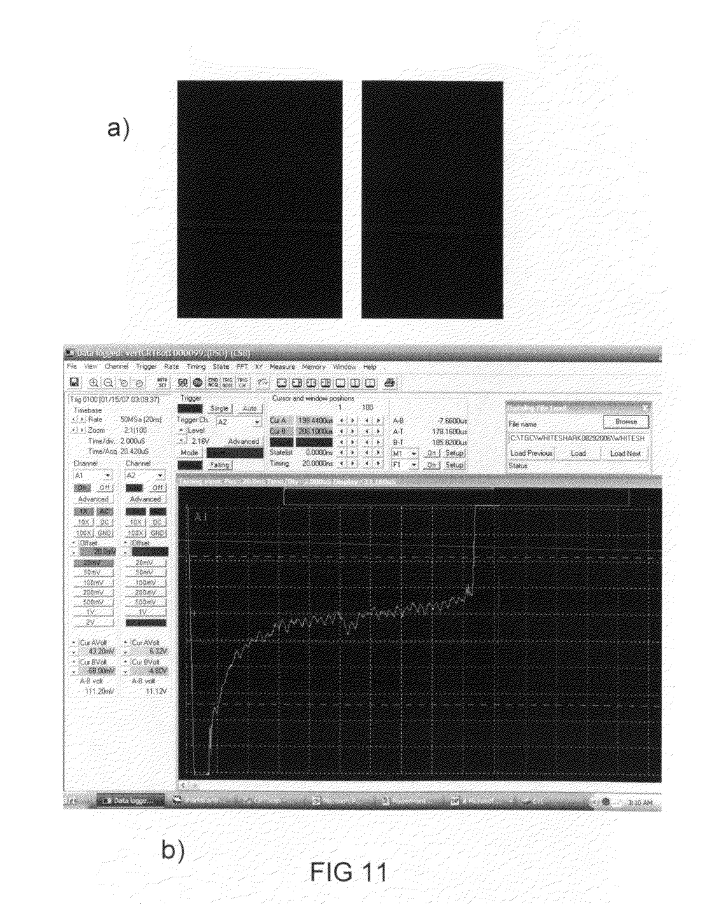

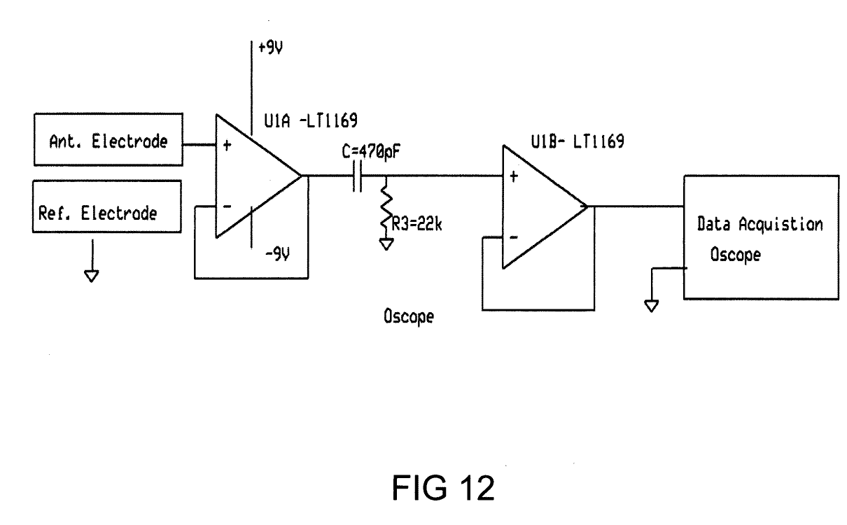

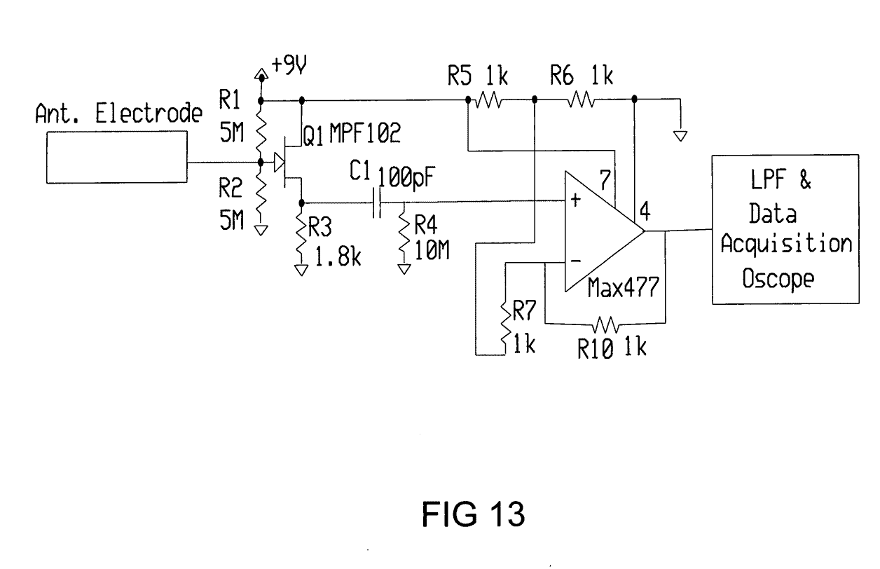

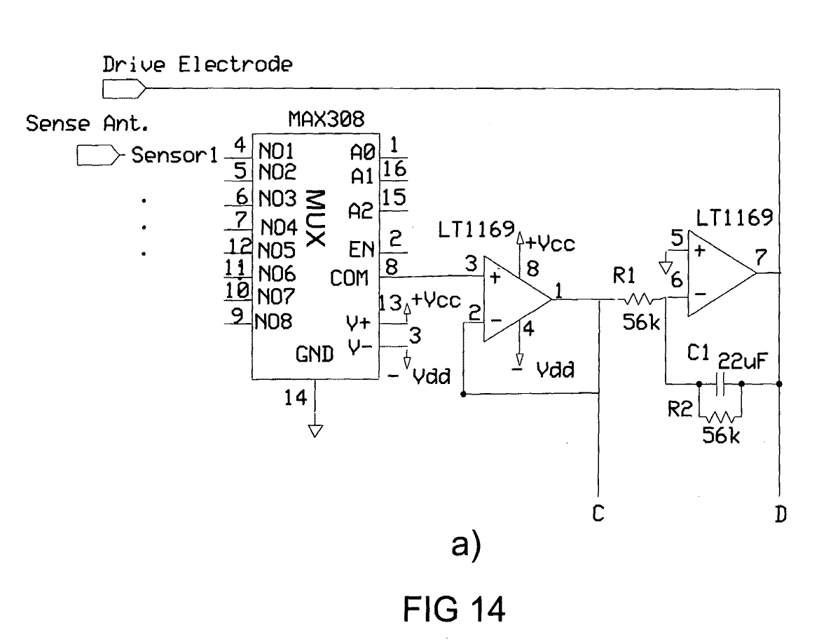

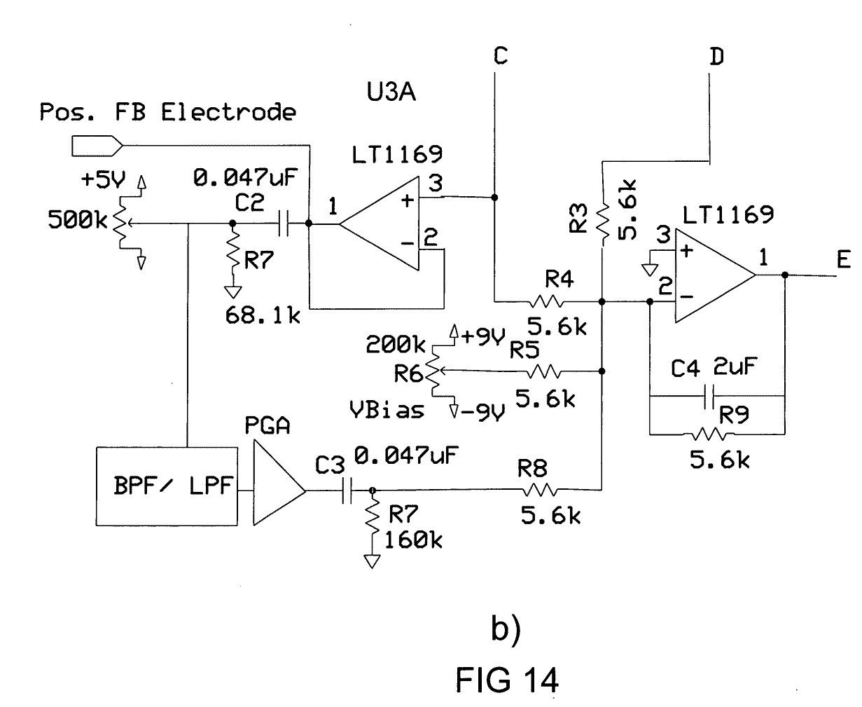

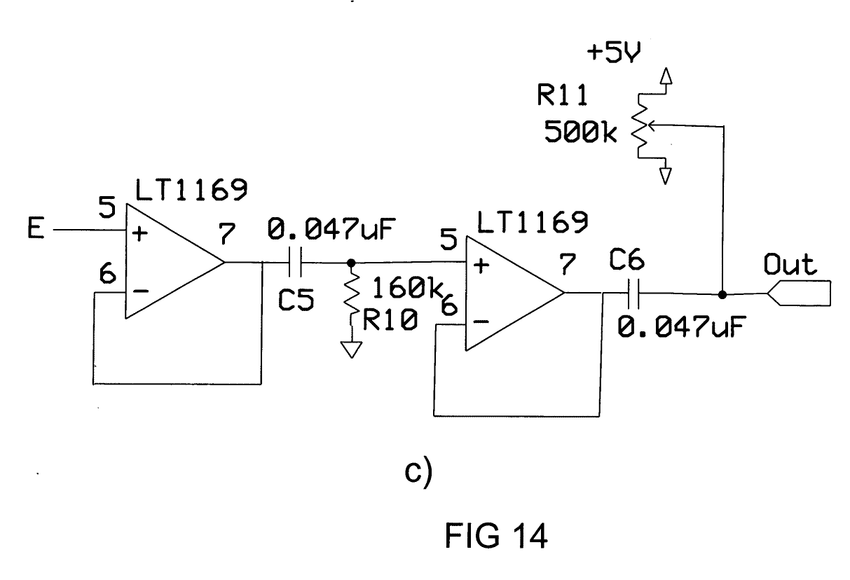

Next it is realized, and planned for that the signal detected from a computer monitor is used to create an image of objects between the monitor and an E-field sensor. The E-field sensor detects a negative going signal, or decreasing signal level when the electron beam illuminates a spot on the CRT. This signal is displayable on another display monitor by sending in the E-field sensor signal to a display as a color signal. It is most easily displayed on a monitor that processes analog video signals. What is to be done is the line sync, and frame sync from the monitor used to produce the E-field source, are feed to a second monitor. Then the output of the E-field sensor is signal conditions, buffered or amplified with a video amplifier, like the 300 MHz bandwidth one discussed above, if the MPF102 amplifier is used, like in FIG. 10. The DC level is shifted so the signal appears as needed, and then sent into as the color signal. When the Red, Blue, and Green, inputs to the second monitor are all connected to the conditions E-field sensor output, an black and white image is formed. The image of the object is formed when a white background is displayed on a CRT that generates the E-field source. Other color levels on the CRT E-field source reduce the E-field signal level coming from the CRT. The decrease are seen respectively. Placing an object between the CRT source and the E-field sensor results in an E-field image of the object.

The E-field sensor antenna can be a small patch on the optical axis or center line extending normal to the CRT, but out from it at its center. Switched in electrodes are also possible, at different locations. This way the view point of the image is changed. If a large electrode is used then all signals come from the E-field source points on the CRT are detected at different locations. This can improve signal level, but also result in image degradation because the rays from the E-field source are hitting the sensor electrode after traversing different paths through the object or body being scanned.

Digital data collection with signal processing gain is also possible by capturing a line of data on the digital Oscilloscope and saving the data for further processing. The data collection is done coherently. This is the signal is believed to repeat its self in a periodic way, every frame, with a certain time to each line. By triggering the data collection with a frame and line counter. Line data can be repeatedly collected, saved, and then increment to the next line and repeat the processes. By doing this for the desired lines available, then scan is completed. These signals are processed, trimming out unnecessary signals, like the line sync. signal that appears in the E-field line signal capture. Then time aligning the signals to compensate for any jitter in the clock if any, then averaging in time the signal. The averages are done for each line data set. This reduces the noise and improves the signal to noise ratio in the scan. The signals are then displayed as an image. This can be done with a display program from the computer, or signal conditioned and played through a digital analog converter to an analog display monitor, or converted to digital data for a display on a digital monitor, either a compute or to a TV display.

### Pixel Detection:

The next question to answer was can the E-field sensor detect the electric field produced by a pixel of a computer monitor? If so, then imaging and additional control can be performed with the E-field sources from a display monitor.

To answer the question some experimentation commenced. First the left hand touched the CRT and then the right hand touched the MCS2 sensor covered by the notebook. The MCS2 sensor is a floating input opamp design E-field sensor.

The MCS2 sensor had the reference electrode biased near −VCC so the AC signal would decrease. Signals were observed but it was not clear what they were or meant. The low frequency background signal of the 60 Hz, dominated the signal. The signal had many harmonics and it was unclear what was going on. The refresh rate was distinguished from the 60 Hz background by changing the screen vertical refresh rate. The computer monitor was initially displaying the desktop.

Next a C++ program was written to make the screen appear black with the exception of a white patch. A antenna of the MCS2 sensor was placed on a CRT with ½ in. wide copper tape from 3M corporation. It is noted the DC bias is low since the screen seems to be at or close to ground potential. No attempt was made to shift the DC to allow for AC amplitude decrease. It seemed that the refresh frame was detected but there was much structure.

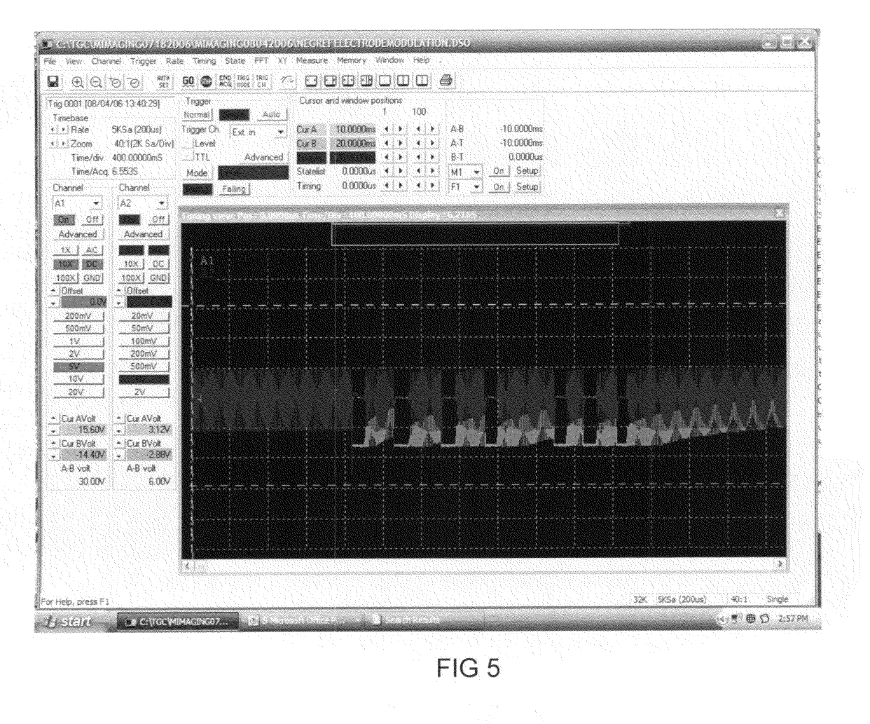

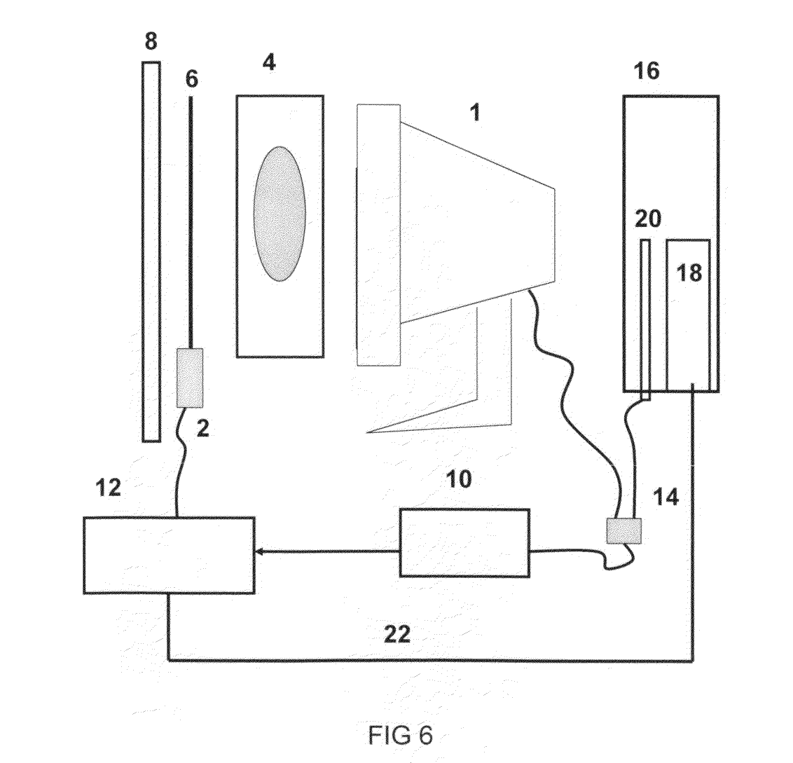

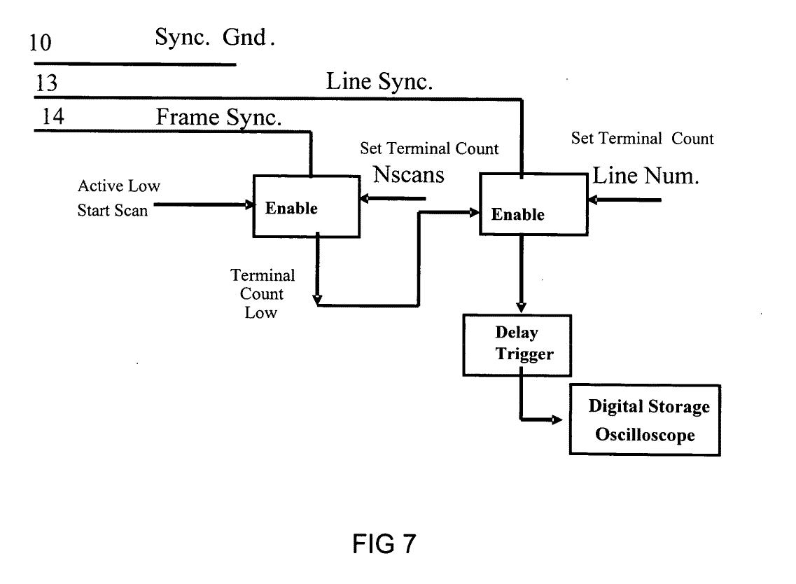

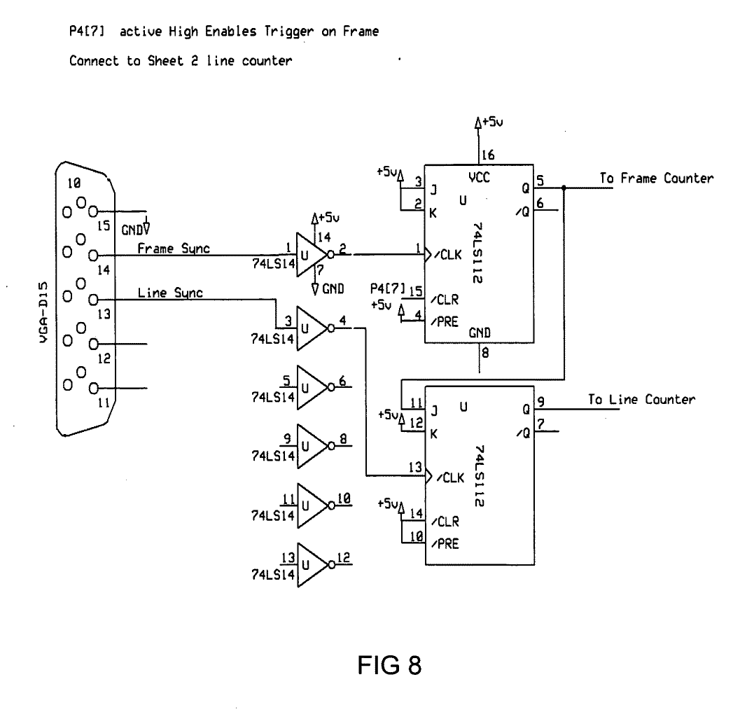

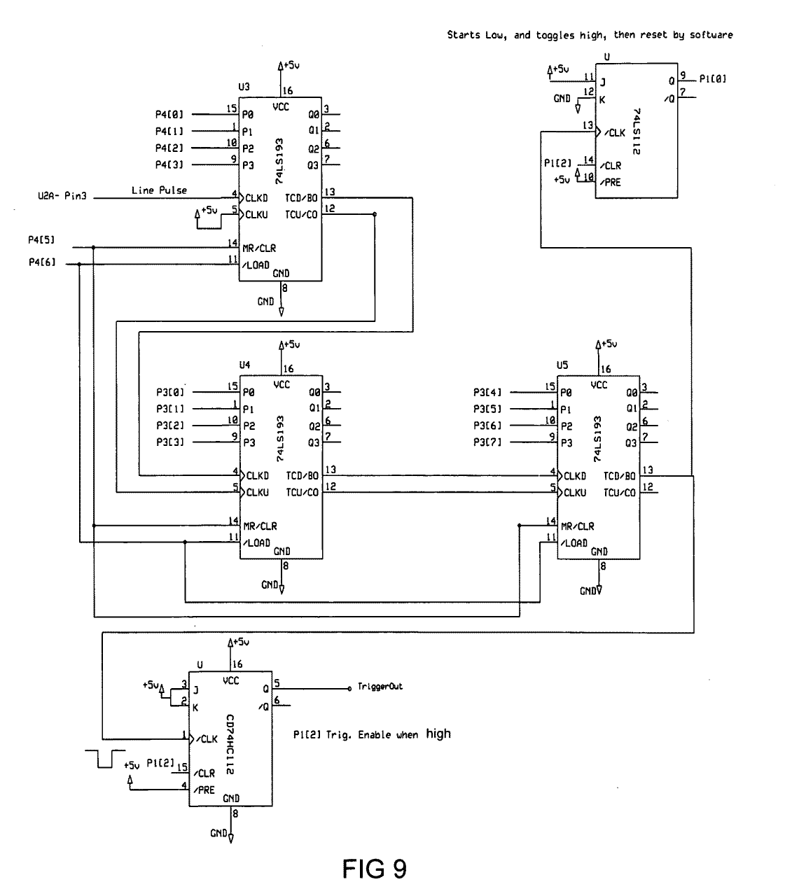

To see the CRT pixels signal with the MCS2, having no reference electrode, The pixel bar needs to have a response that is long enough to produce a pulse with a bandwidth of the TL082 is only about 4 MHz at unity gain, and the LM1169 is about 5 MHz. Further, the signal needed filtered to detect it with the oscilloscope. A high pass single pole filter was placed after the unity gain amplifier. The filter was formed with a 470 pF capacitor, and 22 kOhm resistor, to give a corner frequency of about 15 kHz. The filter allowed the observation of the E-field signature from the white patch. A vertical white bar was eventually used, since it was realized that a line scan of the CRT had a negative going signal that was detected and associated with the white pixels on the line. The digital oscilloscope was set to 20 mV per division, that adds a voltage gain of near 50. A sample rate of 20 MHz was initially used with high gain of about 50. The white patch places all three electron beams to a location on the screen. An E-machine CRT was used in 600×800 resolution, at a frame rate of 60 Hz. The signal of the CRT was well observed as shown in FIG. 5 when the MCS2 antenna electrode was stuck on the face of the CRT. The position was not important because the signal travel at the speed of light through the glass. The location relative to the beginning of the line changes as the white vertical bar is moved from horizontally.

The same circuit was used to sense the line spectrum from CRT and Flat screen monitor Sanyo LCD were able to generate a background from either the refresh rate or the line scan frequency. These backgrounds were found useful for a motional command system MCS, and tested for 60 Hz to 85 Hz for the frame rate, and about 40 kHz to 60 kHz for the line frequency. To make an E-field motional commands system operate best at a frequency of the line scan frequency, and a band pass filter was implement after the first stage to avoid digital aliasing, and to allow for the line frequency to pass cleanly. The high pass filter was followed by a low pass filter with C=470 pF, and R=100 k. The MCS2 sensor was able to operate without an electrode on the CRT or FLAT panel and detect the line frequency.

However, to see the Pixel from a MCS2 antenna mounted 8 inches away from the CRT face on a vertical ⅛ thick glass plate that added a new twist was needed. In this case, the antenna was far enough away from the grounded screen that a bias of −3V to −5V existed. This was compensated for by placing a ground plane of 12 inch wide by about 18 inches high. The ground plane was a cookie sheet, and set up at ranges of an 1 inch to 4 inches behind a ⅛ inch thick glass plate. It was necessary to reduce the DC bias out from the 1^{st} stage of the MCS2 opamp to provide enough sensitivity to sense the signal. When the line sweep starts it is seen a large swing voltage. This occurs on CRT and OP Amp.

To trigger the oscilloscope in a repetitive way to get coherent data, a trigger circuit was made. The trigger circuit counts the number of lines beginning with a frame signal. The control lines from the PC computer to the monitor were found to have a vertical and horizontal line synchronization signal. These signals were feed into the counter by a VGA cable splitter. Upon a specified line number, the terminal count sends a TTL signal to the oscilloscope to trigger the collection. An automatic data logging routine is used to save the data to disk for post processing. We digitize the E-field sensor data at 50 MHz, and capture about 25 microseconds of 8 bit oscilloscope data per capture.

The data collection for an image scan is done by rastering the location of the E-field source using a C++ program that communicates with the trigger microcontroller. The power of the illuminated section or E-field source region is computed In the case of having smart controls or buttons locations the trigger circuit captures the E-field data on the lines where the buttons are drawn. The average power over the illuminated spot or the button is computed by first extracting only the data of interest, removing the mean and then computing its variance. A running average can be taken to help smooth out the data. It is updated on every frame.

Further processing of the image is also possible or filtering of the data. Multiple buttons can be drawn to track a gesture. Thresholds are set to assist with quantization and detection logic for the image and the smart buttons respectively.

### Proximity Detection

E-field background signatures are able to be precisely associated with drawn shapes on a computer screen when the location of the shape is specified a priori. This is usually the case, as a program window moves or a button is located on a video screen. The location of objects shown on the screen is known, so the video card can send the signal to the location on the screen and create the image. Object locations are commonly given to a programmer by operating system calls, or specified by the creator of the program, or the use when it is moved.

Any of these means of detection are possible, but now the buttons drawn on a screen through a display program are made sources of the E-field as the background. As the person moves proximate to the button with a control object, such as their body, finger, or stylus, the E-field proximate the button changes. An E-field sensor having a means of detection as stated above is used and placed within the display unit, or proximate the display to sense the E-field changes. Decision logic is then applied to the sensor signals and the operation associated with the control is executed by the machine.

Technology to this date offers a separate sensor physically adhered at positions on the screen, or provided by another layer of material. Touch sensitive video screens have been available for sometime, but are still quite expensive. They are cost prohibitive for large screens like flat panel TVs. Some are acoustic, and most are wire resistive types. The position of contact is found by measuring the resistance in a wire mesh network. These screens require special interconnections to sensor pads and electrodes at the location of where a control is to be placed. Thus these approaches are add-ons to commonly available video monitors, and thus are not available for ubiquitous computing, and TV viewing.

There are other embedded sensor technologies, like capacitive sensing where the capacitance between two electrodes is increased by body coupling. Cypress Semiconductor has a capacitor sensor that requires an electrode pattern to added. Again, a sensor electrode is required at each location of the control button.

These control sensor technologies also lack the range and material penetration ability compared with E-field sensors and thus do not have proximity, gesture or general non-touch capability, nor do they allow sensor penetration through a body for imaging or identification. Also the above sensors for controls are not programmable to a location on a non-specialized display or an affordable display that can be shipped as a ubiquitous display product.

Thus what is needed is a simple way to program the placement of a control on a display. Also what is needed is a simple way to reduced the sensor count needed to detect the signal from a control. Also what is needed is a way to reduce the complexity of the interconnections to sensor pads.

### E-Field Imaging

Electrostatics fields occur all around us, and are safe from ionizing radiation. A key interest in medical imaging is the reduction of radiation dose. The ability to perform radiation free imaging from a computer screen is also intriguing. E-field imaging and sensing is also a phenomenon that nature has equipped a shark, and thus use the trademark of Whiteshark™, and Whiteshark Imaging™.

A common use of electrostatic is in a photocopy machine or laser printer. The optical picture of the surface of an object is recreated by placing charge on the paper at locations to attract and hold the toner particles where the dark spots are on the photo being copied, then follows with the melting of the toner on the paper to make the picture.

In contrast to a photocopier, the new machine in this invention makes a picture of what is inside an body. It does so by placing electrostatic charge on a panel in front of the object and then displays an image of the signal detected behind the object. Foreign objects or inhomogenities within the body change the electric field as it travels through the body. These changes in electric fields are seen in a E-field scan image and appear as contrasts in the signal strength, and phase detected by the E-fields sensor technology.

To make the image what is required is a means of placing the E-field source at a time and spatial location that is time synchronized clocked in a way that the E-field sensor signals measured can be correlated with the pixel that generated them. The reference signal for the correlation can be measured by an E-field sensor having a sensing electrode on the screen or on the body of the person.

Next we detect the signal with an E-field sensor as it propagated from the source to the sensor, and processing the signals to make an image.

In the CRT the glass conducts the signal well, without much loss to a conducting antenna. In a test, the author used a 9 inch long, by ½ inch wide copper strip glued to the glass with peal back adhesive. In some application, it may be necessary to add an E-field conductor such as glass or electrical conducting wire or plate to help conduct the electric potential from the location of deposit to the location of the sensor. The electrode dimensions are not too critical, but the capacitance to ground should be minimized to allow for fast response and maximum bandwidth of the E-field sensor.

It is also recognized that capturing a photographic image from within a computer screen is also possible with the disclosed E-field coupled technology. This is done by coating the display screen with a light sensitive film or matrix of such elements that produces charge or E-field upon receipt of a photon. The charge has to be amplified significantly but once deposited on the display, the E-field propagates at the speed of light through a conducting covering material to a E-field sensor antenna affixed to the screen. We then monitor the change in E-field signal associated with the light exposure, and map it for each pixel to make a picture. The method is similar to that described with the CRT when an E-field sensor antenna is affixed to the glass of the CRT, with the exception that the charge originates from a photon-to-charge or voltage converter instead of the electron beam.

If a nonpixelized photosensitive film is desired, then a single sheet can be placed below the polarization filter in an LCD. The LCD pixels can be used as an optical switch to only allow light to hit the photosensitive sheet. The photosensitive material can be placed on a transparent conducting material. When charge is generated, it at a transparent pixel location, the voltage is detected by an attached electrode to the conducting sheet.

### PREFERRED EMBODIMENT

A scan is a collection of E-field sensor signals obtained when the position of the E-field source is moved, or the location of the detector, or both of these. Changes is sensor signal amplitude and phase are displayed as an image. Inhomogeneities in the electrical properties, or electromagnetic such as dielectric constant, permittivity, and conductivity along with the attenuation due to thickness variations of the sample are observed as contrasts.

Variations in thickness of the body over the scanned region may be compensated via additional thickness estimates obtained from ultrasound, optical, acoustical, or E-field proximity sensing from external measurements. Thickness correction is done with the assumption of homogeneous material. For example knowing the thickness of the body at the scan allows for the normalization of the E-field measurement to a unit thickness.

If the uniform assumption fails, then image pixels or image regions will show contrast due to inhomogeneous electrical properties, dielectric constant, polarizabilty, and conductivity for example, that may be indicative of material inhomogeneity such a density changes, or atomic or molecular changes. If multiple layers are present in the body, then the assumption is applied for each layer based upon known measurements for those materials, for example body tissues such as bone, muscle, and fat may have differing dielectric or properties that allow for contrast in potential produced by an incident electric field.

This disclosure shows how to digitally generate and control the necessary electric fields, and how to collect and process the data to construct an image of the variations or contrast of the electrical properties of a body as seen though its thickness from one side to the other of the body.

### Source Electrode an E-field Generator:

The method in this invention requires the act of applying an electric field to a body from one side, and then observing on the opposite side of the body the detected electric potential as indicated by the signal output of an E-field sensor. The applied electric field is produced by a deposited electrical charge on a source-electrode positioned in front of the body. The location and time the charge is deposited is known by design of what we call the E-field generator.

The source-electrode is an object that holds electrical charge. The source electrode can hold charge statically, or by a battery or power supply source. Importantly, the source-electrode must generate an electric field that emminates toward the body upon being activated or turned on. Thus is can be activated mechanically, electrically, chemically, or optically, or by some other means. The source electrode can hold the charge for a period of time, or even turn on and off to give a frequency, or oscillate about positive and negative voltage with a frequency. The frequency requirement depends upon the material being scanned, but generally lower frequencies penetrate more deeply through material. Even DC signals are useful, where the frequency does not change over the duration of the measurement, and higher frequencies are too.

The source frequency, and its repetition frequency must be controlled well enough to allow for repeated measurements with good coherence between measurement. This is done by triggering an E-field sensor voltage measurement at repeatable times with good enough precision to allow for coherent measurements of signals for a source at a specified and known location. Thus the phase of the detected E-field signal from the source generator is aligned from measurement to measurement. Hence, random noise cancels, and signal processing gain is made possible through averaging of sinusoid. If the waveform from the generator is not sinusoidal, but for example a pulse, occurring with a charge deposit, the Fourier transform is performed prior to the coherent averaging.

Also we require that the source-electrode is movable in space, i.e., its spatial location is changeable upon command. If the same source electrode is not mechanically moved, then the source-electrode must also have the ability to be commanded to turn on and off, and then to switch or turn on another source-electrode at a different location, thus giving the equivalent effect of moving the source-electrode.

The source-electrode may be any means of holding charge. For example, it may be an electrical conductor, insulator, or semiconductor, in the shape of a wire, a plate, or of other geometry. It can even just be a molecule or atom deposited on a substrate, or even in a higher level device form such an electronic component such as a device such a FET, transistor, or gate, or in a simple compound form such as a semiconductor interfaced with other material.

### Imaging and Proximity Detection

A reason why E-field imaging and computer smart controls are now made possible with this invention is because of the achieved very precisely controlled placement of the charge in space and time. The method is demonstrated in this application with the use of a CRT computer monitor that was convenient for the demonstration of the method, and to claim the invention. It is possible to construct other hardware specific to the application, and the device used to generate the E-field for imaging may not necessary need to be a video device. For example, to perform imaging at low frequencies, it would be preferable to use a CRT such as in the oscilloscope, or a customized electron gun like those used in the semiconductor industry for manufacturing integrated circuits. In these devices, the electron beam can be held at a location for extended period, and is not necessary scanned at a specific line and frame rate. The duration of on time of the source is related to the frequency of the E-field source.

It is realized that to operate at other frequencies, or to have more signal output, or the inclusion of focusing effects, other devices can be desired with the appropriate funding. Those familiar with the art of electronics will be able to use this disclosed information to make use and construction other hardware and software to image and detect proximity from both display type and for nondisplay devices, but non-the-less these are covered in the claims of this invention.

On the other hand, for programmable smart controls on a computer screen, another type of more ready available video display such as LCD, or plasma display may be a preferred embodiment because of their geometry and weight. Those displays also have the characteristics of CRT as their response time increases.

LCD signals seem to require more amplification and processing to see the pixel signatures. It may even be practical to manufacture the LCD or other digital display technologies to have a matrixed electrode pattern, where each matrix element is formed within a layer of the pixel, called pixel electrodes. Such a layer can receive the charge from the capacitor or a voltage used in the active matrix LCD displays, and conduct the signal to an E-field sensor. As with the CRT and E-field sensor can be connected to the pixel charge conductor as a substrate sheet. The conducted E-field signal can be used as a reference signal to provide illumination waveforms, and used in a cross correlation with detected signals by an E-field sensor or plurality located away from the display. The pixelized electrodes would then send out the E-field from the location of the pixel that was turned on. Care needs taken with LCD as the voltage is applied when the screen is dark, and off otherwise. Also it is common to reverse the drive voltage of the LCD pixels between frames, or sometimes lines.

The added pixel electrodes if used in the display act as an E-field source generator that is synchronized with the pixel illumination of a programmed control location or region on the video display. This synchronized source generator, is needed if there is not enough signal to noise ratio to pick up the E-field from the pixels of the screen at the location on the screen where the source is desired. It is in other words just a booster or repeater that is interfaced with the video timing to generate the source field. The E-field from the boosted source in a display is then used to be modified by the approach of a control surface or the electrical properties of a body in the same way as an unboosted source. There can be many variation of the how to get this source in a video display, but from the description of the CRT, we see that those skilled in the are can make the system with other displays, or nondisplay semiconductor manufacturing technology. So what is claimed is to have a pixelized E-field source generator with a precisely controlled location.

Digital video displays also the use of digital interfaces, but these are understood by those in the art of video or by manufactures of video cards, multimedia devices, and TVs, and can implement the synchronized of the data collection on the E-field sensor with the illumination of pixels on the display. In some cases, reverse signal logic can be used between different display technologies, that is the E-field signature looks different when a pixel is turned on or off

### DETAILED DESCRIPTION

Our imaging method assumes to first order that the electric field travels in straight lines from the source to the detector. The electric field is generated by precisely placing or depositing a quantity of charge quantity at a know physical location at a known time, or so called the source location. The electric field produced by this quantity of charge is then detected with an E-field sensor. The electric field is detected as a voltage occurring in time via a digital oscilloscope or equivalent voltage detection circuitry. The detected electric field is measured relative to a background occurring with the absence of the E-field source.

The use of a small “pixel” or quantity of charge is significant because the measured E-field response due to a collection of spatially and temporally distributed pixels is just the superposition of the individual pixel responses each time shifted to align the E-field signal responses coincident in time. Thus, the E-field measurement produced by an extended source occurring at a single instant of time say at t=0, can be equivalently created by generating a time-sequence of a spatially distributed charge sources pixel, measuring the sequence of E-field responses of n locations, say E0(t=0), E2(t=1), . . . En(t=n) and then time shifting all these response back to time t=0.

Thus the effect is the generation of all possible source fields by measuring the response of a pixel moved around in space to a spatial location of coordinates x,y,z, and turned on at a time t, making the E-field measurement, collecting the digitize E-field sensor voltage signal amplitude with time, and then processing.

It is useful to generate a focused E-field to help with contrast and provided higher signal to noise ratios to image an object within a body at a particular location. This is done by controlling the quantity of charge or magnitude, and the sign. Charge has polarity, and thus in electrostatics we deal with positive and negative charges. A physical way to get positive and negative charges at the pixels is by depositing positive or negative charge on the pixel from a source of charge such as a battery, or electrostatic source, or other source of positive and negative electricity.

Our preferred digital method is to multiply the measured digitized E-field response from a pixel by a negative sign. To adjust the magnitude of the charge, we multiply the E-field response by a multiplicative factor associated with the magnitude of charge as opposed to physically depositing more or less charge on the pixel.

Up to this point in our discussion, we have not discussed the phase difference between the E-field response due to path length differences between two pixels and the sensor location. This is because it is generally negligible for the case for low frequency waves E-fields, where the electromagnetic wavelength is much much larger than the spatial region over which the E-field is to be generated by the source.

However phase is important in focusing or beamforming, and we do it mathematically by artificial constructs. First knowing the source location and the detector or synonymously the sensor location, we shift all time record obtained from each pixel source so they time align, or arrive at the same time to the detector location. The time record of each pixel measurement are processed to get a good average E-field time response from each pixel. The processing can be demeaning, filtering, then averaging over all collected signature for each time sample. Next the amplitude of the detected signal is computed by time gating the signal. This can be a representation in voltage amplitude or a frequency amplitude, but we choose a voltage amplitude averaged over the frequency band of the signal.

The bandwidth of the detected E-field source is related to the pixel E-field source time. In the CRT this is how long the charge is held on the screen. In the CRT, it has a minimum of the time to pass an electron beam across the pixel region producing the E-field source. The pulse would have the bandwidth of 1/source time. It is possible and useful to use a grouping of pixels to reduce the bandwidth as commensurate with the E-field sensor.

Note the E-field frequency is the time rate at which the source pixel is turned on and off. The E-field frequencies are lower that what can be physically focused by the array spatial extent. In other words, the E-fields have frequencies with wavelengths longer than that of the spatial dimension of the E-field array of the display screen. Thus what is needed is a mathematical trick to focus E-field signals from all of the individual pixels.

To digitally focus, we mathematically modulate the processed amplitude signal with a complex sinusoidal waveform by multiplication by and exponential, exp(j*2*pi*f*t). Here f is the desired frequency that the focus will be done at, and t is the time of the collected trace. It has to be digitized, and we see that the digitized representation is exp(2*pi*n*k/N), where n is the time sample index running 0 to N−1, and k is the frequency index running 0 to (N/2−1). N is the number of analog to digital samples captured in the analog to digital converter(ADC). To focus digitally, we need faster than the frequency we are going to apply, a sample rate greater than 2f is needed but more is better, so say it is 10f.

The speed of light travels at 30 mm per nanosecond. To have high frequency implies a high focal resolution given by the order of the wavelength of light at that frequency. For a frequency of 1 GHz, the wavelength in free space is 30 mm. To beamform say at 1 GHz, we need to sample at 10 GHz in our example. The aperture size of the scan of pixels can must be greater than the simulated wavelength to focus. Thus say a ratio of 10 is acceptable to get narrow beamwidth, then we need a screen with source fields that is 3 m wide. If we bump up the beamforming frequency and sample rate accordingly, a 30 mm wide panel will operate with good beamforming for a f=10 GHz, and a sample rate fs=100 GHz. The wavelength is then 3 mm. Next we have to be in the far field for plane wave type beams, this is (30²)/3 or 300 mm. This is practical to scan a body. Next the beamsteering weights are applied to each source pixel signal now being complex with an amplitude and a frequency. These apply an additional phase correction that depend upon frequency and the distance from the pixel to the detector location, such as exp(j*2pi*deltaR/lamda). This is the usual beam steering factor to focus a beam to detector location, where deltaR is the pathlength difference from the source pixel to the detector measure relative to the distance from a pixel in the center of the screen to the detector position. Lamda is the wavelength of the simulated beam. This steers the beam of all the pixels to the detector location by introducing the necessary phase delay from each pixel. Then by summing all these signals from each pixels with the applied weights, we get the result of having transmitted a focused E-field from a complex distributions of E-field sources to the detector. By moving the detector to another location and performing the data collection and processing again accordingly, another focused signal will be obtained.

The focusing processing depends upon Green's theorem that states the response of a signal from a distributed source is that from a collection of point sources. In the disclosed measurement process, we collect with our E-field detector the response due to points source E-field generators. We collect the signals over time from a simple raster of sources, and weight the signal according to linear theory. To have high resolution in medical imaging, we want to focus the E-field to a location within the body and look at the detected E-field at the detector. What was demonstrated here in this algorithm is a far field beamformer. Near fields are also possible. The ability to have high sample rate ADCs, makes for precise time sequenced and coherent data collection.

When there is enough signal strength from each pixel, then a image can be formed without the beamforming by using a single pixel. The processing algorithm describe here will work for other amplitude measurement if the signals are obtained from each pixel. This could be the case of using an optical measurement where light is transmitted and detected. It could also apply to X-ray, since if there were no lead in the glass of a CRT, an X-ray does would be produced to the body. If we have a means of turning on an aperture and controlling the dose of X-rays produced by the CRT pixel, then a raster scan of the pixels will allow for capture of X-ray photons in the detector.

1. A method of using a spatially and temporally modulate array of pixel voltages or equivalently charges call the active source is placed on a surface at a specified location x,y,z so as to provide a point source of E-fields for image where next
i. A body is placed between surface and a E-field sensor;
ii. The active source at the location x,y,z is turned on repeatedly and a signal is collected coherently in the E-fields sensor system;
iii. The E-field digitized signal data is stored in a computer;
iv. The position of the source is moved and the E-field collection of ii is performed again;
v. The E-field digitized signal data is stored in a computer;
vi. The process from ii though iv is repeated so a volume of rays were swept out from the sources positions through the body being scanned to the E-field sensor;
vii. The E-fields sensor position is moved and the process from ii through vi is repeated;
viii. Process vii is repeated over a volume of rays were swept out form the E-field sensor to the each active source location;
ix. An image is created from the attenuation in the body;

2. A apparatus of a smart-control is made by turning on electrical pixel voltages or equivalently charges on a region on a video screen. An E-field sensor is used to detect when a persons moves their finger close to the smart button;
